(19) United States
(12) Patent Application Publication
(10) Pub. No.: US 2025/0103763 A1
(43) Pub. Date: Mar. 27, 2025

(54) SIMULATION APPARATUS

(71) Applicant: Mitsubishi Electric Corporation, Chiyoda-ku, Tokyo (JP)

(72) Inventors: Shu ICHIKAWA, Tokyo (JP); Michiyasu HIRAMATSU, Tokyo (JP)

(73) Assignee: Mitsubishi Electric Corporation, Chiyoda-ku, Tokyo (JP)

(21) Appl. No.: 18/832,525

(22) PCT Filed: Mar. 18, 2022
(86) PCT No.: PCT/JP2022/012727

§ 371 Date: Jul. 24, 2024

(51) Int. Cl. G06F 30/17

(52) U.S. Cl. CPC G06F 30/17

(57) ABSTRACT

The present disclosure relates to a simulation apparatus and includes: a coupled simulation unit that performs coupled simulation to combine a plurality of micro-models each being a simulation model for a limited element; a macro-model learning unit that learns, from a result of the coupled simulation performed by the coupled simulation unit, a correspondence between an input and an output in overall simulation to simulate an entire simulation target and generates a macro-model to infer an output after a period of time has elapsed for an input; and an overall simulation performing unit that performs the overall simulation using the macro-model generated by the macro-model learning unit.

### TECHNICAL FIELD

The present disclosure relates to simulation apparatuses and relates to simulation apparatuses with reduced calculation amounts.

### BACKGROUND ART

Efforts have recently been made, in product development, to front-load verification and a test of behavior of a product at a design stage using a simulation model to simulate the behavior of the product. This enables pre-verification of new technology and early detection of a failure at the design stage, so that costs required for verification can be reduced, and time to develop a prototype can be eliminated to reduce a period of time for development.

To simulate the behavior of the product, it is necessary to simulate interactions among various elements of the product, such as operation of various actuators and behavior of embedded software, a variation in framework, and an environmental change around the product, for example. It is also necessary to verify whether a result of the simulation and behavior of an actual product reasonably match.

For all of these reasons, development of a simulation model to simulate behavior of an entire product often involves significant costs, and simulation of various combinations of elements relating to the product is necessary to verify the validity of the model.

Thus, in utilization of the simulation model in product development, there is a case where a simulation model limited to a single element of the product, such as behavior of software on a substrate and a load of an actuator, is developed and used for product development. An element simulated by such a simulation model is limited, so that the validity of the model can be verified by simulation on fewer conditions.

On the other hand, the limited simulation model cannot verify operation and control of a plurality of elements, such as output adjustment according to the load of the actuator and a change in airflow generated by a fan.

It is thus contemplated to combine existing partial simulation models for implementation instead of developing a simulation model to simulate behavior of an entire product or operation and control of a plurality of elements. Patent Documents shown below are documents relating to simulation models.

Patent Document 1 discloses, in terms of an increase in efficiency of a calculation amount of a simulation model, a method of selecting a representative point representing behavior of a simulation target and using a model having learned only behavior of the representative point to reduce a calculation amount required for simulation.

Patent Document 2 discloses, in terms of expansion of a range in which a simulation model is applicable, a method of learning a result of simulation performed by an existing simulation model, generating a learning model to estimate a similar output while determining accuracy of a value estimated by the learning model, and performing relearning when the accuracy is insufficient estimation accuracy to enable simulation under a condition not covered by existing simulation.

Patent Document 3 discloses, in terms of improvement in prediction accuracy of a simulation model, a scheme of optimizing a parameter of the simulation model using data obtained by excluding a time-varying component from measured data used for optimization and correcting an output value of the optimized model using the excluded time-varying component to solve reduction in prediction accuracy due to optimization of the simulation model using a measured value.

### PRIOR ART DOCUMENTS

### Patent Documents

Patent Document 1: Japanese Patent Application Laid-Open No. 2020-060996

Patent Document 2: WO 2018/143019

Patent Document 3: Japanese Patent Application Laid-Open No. 07-056608

### SUMMARY

### Problem to be Solved by the Invention

When simulation models (hereinafter referred to as micro-models) for existing limited elements are combined for simulation instead of developing a simulation model (hereinafter referred to as a macro-model) for an entire product or a plurality of elements, each of the micro-models requires more detailed simulation than that required by the macro-model. For example, in an air conditioner, when behavior of a control board is simulated, it is important to simulate a process of computation performed by control software, and simulation in units of clocks is required. On the other hand, when behavior of the entire air conditioner is simulated, not a fine change inside the control board but a change made by multiple elements, such as a change in airflow due to operation of various actuators, a fan, and the like is important, and simulation in seconds or in minutes is required. This results in a problem, in coupled simulation to combine micro-models, in that it is required to perform simulation in finer time units than those for a single macro-model, leading to an increase in calculation amount.

In a scheme disclosed in Patent Document 1, it is required to select the representative point representing the model, so that the representative point cannot be selected by a model, such as the control board, in which each signal output has a meaning, and the scheme is not applicable to the model.

Patent Document 2 discloses a scheme of configuring a model to infer a convergence result of simulation but cannot infer a process of coupled simulation of a plurality of models.

In the scheme disclosed in Patent Document 3, the measured data is required, so that a new mechanism and new control with no measured data cannot be simulated.

The present disclosure has been conceived to solve a problem as described above, and it is an object of the present disclosure to provide a simulation apparatus capable of reducing a calculation amount even when coupled simulation is performed.

### Means to Solve the Problem

A simulation apparatus according to present disclosure includes: a coupled simulation unit that performs coupled simulation to combine a plurality of micro-models each being a simulation model for a limited element; a macro-model learning unit that learns, from a result of the coupled simulation performed by the coupled simulation unit, a correspondence between an input and an output in overall simulation to simulate an entire simulation target and generates a macro-model to infer an output after a period of time has elapsed for an input; and an overall simulation performing unit that performs the overall simulation using the macro-model generated by the macro-model learning unit.

### Effects of the Invention

According to the simulation apparatus according to the present disclosure, a result of coupled simulation in units of times of the plurality of micro-models is learned as a result in units of times of the macro model, so that simulation in units of times of the plurality of micro-models can be omitted in the overall simulation using the macro-model, leading to reduction in calculation amount.

### BRIEF DESCRIPTION OF DRAWINGS

FIG. 1 is a functional block diagram showing a configuration of a simulation apparatus according to Embodiment 1.

FIG. 2 is a flowchart showing a process of generating a simulation model performed by the simulation apparatus according to Embodiment 1.

FIG. 3 is a diagram for explaining processing of shaping learning data performed by the simulation apparatus according to Embodiment 1.

FIG. 4 is a diagram for explaining the processing of shaping the learning data performed by the simulation apparatus according to Embodiment 1.

FIG. 5 is a diagram showing a neural network used for learning of a macro-model performed by the simulation apparatus according to Embodiment 1.

FIG. 6 is a flowchart showing a process of performing overall simulation performed by the simulation apparatus according to Embodiment 1.

FIG. 7 is a diagram showing a hardware configuration to implement the simulation apparatus according to Embodiment 1.

FIG. 8 is a diagram showing a hardware configuration to implement the simulation apparatus according to Embodiment 1.

### DESCRIPTION OF EMBODIMENTS

### Embodiment 1

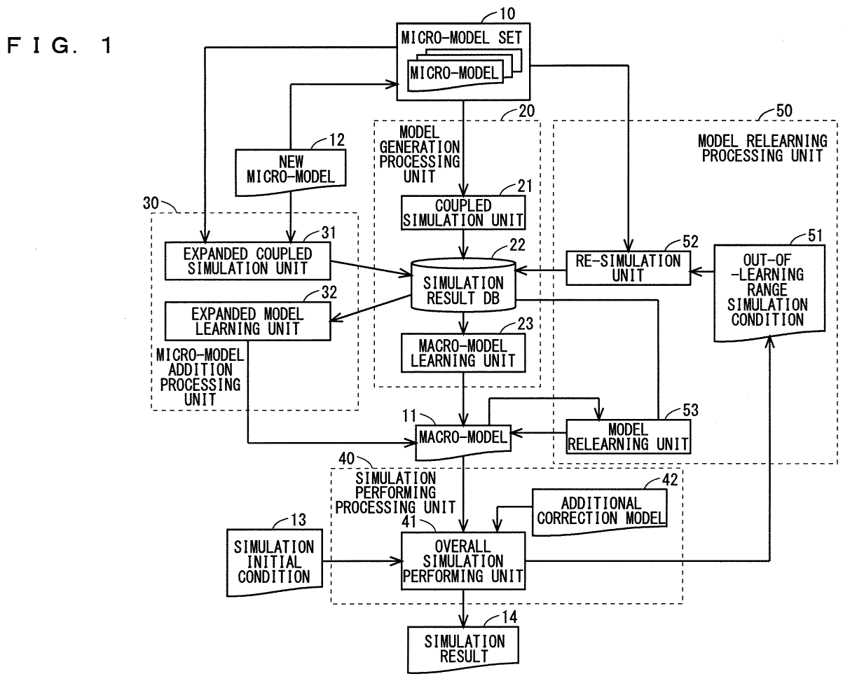

FIG. 1 is a functional block diagram showing a configuration of a simulation apparatus 100 according to Embodiment 1 according to the present disclosure. The simulation apparatus 100 shown in FIG. 1 includes a model generation processing unit 20, a micro-model addition processing unit 30, a simulation performing processing unit 40, and a model relearning processing unit 50.

The model generation processing unit 20 includes: a coupled simulation unit 21 that receives a micro-model set 10 as an input and performs coupled simulation; a simulation result database (DB) 22 that stores a result of the simulation performed by the coupled simulation unit 21; and a macro-model learning unit 23 that generates a macro-model using the result of the simulation stored in the simulation result DB 22, and has a function to generate a macro-model 11.

First, the coupled simulation unit 21 is an apparatus that performs overall simulation using the micro-model set 10, and the overall simulation using the micro-model set 10 is implemented by coupling inputs and outputs of micro-models of the micro-model set 10 and applying an input and an output per simulation cycle of each model to another model.

Processing of “coupling inputs and outputs of micro-models” will herein be described below. In the present disclosure, assume that partial simulation is performed first in utilizing simulation in product development. For example, when an air conditioner is targeted, simulation is developed for each element, such as how a temperature and airflow of a room change due to heating and cooling, whether behavior of a coolant in a coolant circuit and a thermal emission/absorption efficiency change, and behavior of a control board that controls them.

A simulation model for a limited element relating to a product as described above is defined as a “micro-model” in the present disclosure. Simulation for an entire product as a simulation target is defined as “overall simulation”.

Micro-models are generated for respective elements and constitute the micro-model set 10. The overall simulation using the micro-model set 10 is a model that provides an input value at certain time and simulates an output value at time after a period of time has elapsed for each of the elements targeted for simulation.

Specifically, in a case of a simulation model for behavior of the control board, the overall simulation is a model that simulates, upon input of a signal value into the control substrate at time t1, computation processing performed by the control board in units of msec, for example, in units of 100 msec and outputs a signal value from the control board after the above-mentioned period of time has elapsed.

While the models are simulation models independent of one another, inputs and outputs of the respective models sometimes relate to each other. For example, in a simulation model for an indoor airflow temperature, a quantity, a direction, and a temperature of air output from the air conditioner are required as inputs. The quantity and the direction of air are affected by a fan running in response to an output signal of the control board, and the temperature of air is affected by thermal emission and absorption by the coolant circuit. Similarly, measured values of various sensors to be inputs into the control board are affected by the indoor airflow temperature.

As a method of implementing coupled simulation to mutually relate results of simulation performed by the models based on the above-mentioned assumption, as for two models A and B having one or more outputs and one or more inputs relating to each other, applying a mechanism of calculating an input value of the model B from an output value of the model A and inputting the calculated input value into the model B to all the relating models is represented by “coupling inputs and outputs of micro-models”.

When the model A is a model to start simulation for an input at the time t1 after 1 min has elapsed, for example, and the model B is a model to start simulation for an input at the time t1 after 1 sec has elapsed, for example, simulation using the model B is performed 60 times according to a timing at which a result of simulation using the model A is output to match output timings of the results of simulation.

Processing of “applying an input and an output per simulation cycle of each model to another model” will be described next.

Results of simulation might vary among models depending on a system of input even if inputs are the same. Thus, as the method of implementing the coupled simulation, as for the two models A and B having one or more outputs and one or more inputs relating to each other, using an output of the model A at the time t1 as an input into the model B at the same time t1 and using an output of the model A at different time t2 as an input into the model B at the same time t2 is represented by “applying an input and an output per simulation cycle of each model to another model”.

While an example in which various micro-models are collectively input as the micro-model set 10 to generate the macro-model 11 is shown in the block diagram of FIG. 1, the macro-model can be regenerated from the micro-model set 10 as a combination of one or more micro-models newly developed after generation of the macro-model 11 and the macro-model 11. By combining sequentially developed micro-models with the macro-model to regenerate the macro-model to gradually expand the macro-model, application of the overall simulation can be advanced while the macro-model is developed.

The macro-model learning unit 23 is a model generation apparatus that learns, from a result of the coupled simulation using the micro-model set 10, a correspondence between an input and an output and a tendency in the overall simulation and generates the macro-model 11 to estimate an output after a period of time has elapsed for an input.

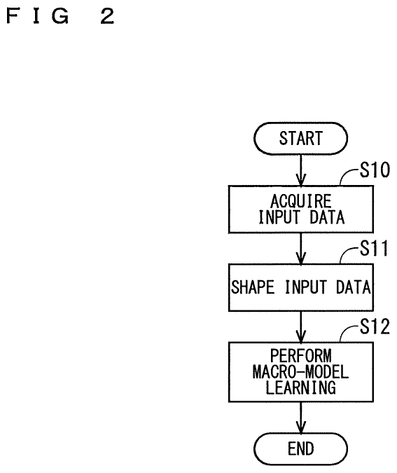

FIG. 2 is a flowchart for explaining a process of learning the macro-model. The process of learning the macro-model will be described below with reference to FIG. 2.

Upon start of learning of the macro-model, the macro-model learning unit 23 first acquires a result of the coupled simulation from the simulation result DB 22 (step S10).

Next, the macro-model learning unit 23 shapes the acquired result of the coupled simulation into an output data pair obtained after a period of time has elapsed for input and output data at certain time (step S11) and outputs the output data pair as learning data.

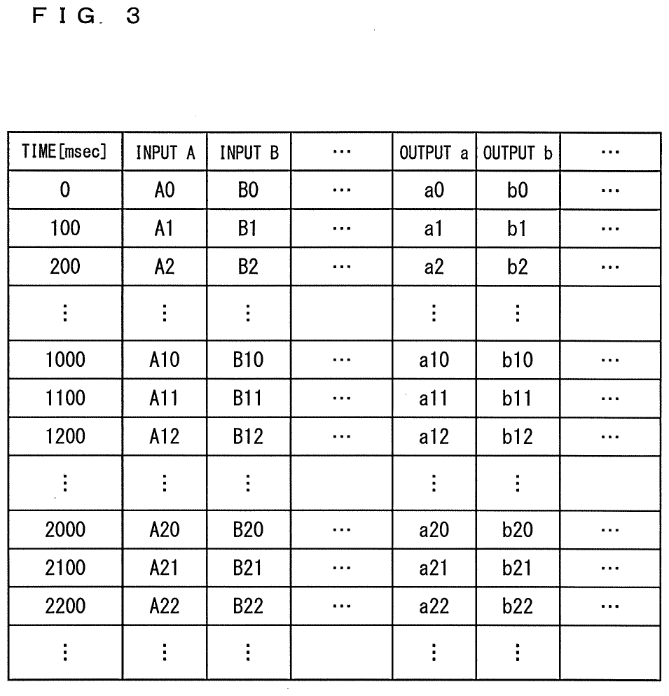

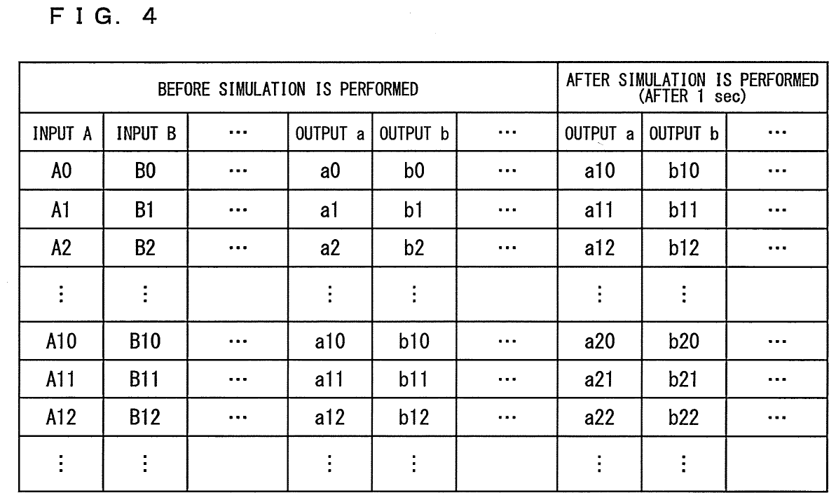

Processing of performing shaping into the learning data in step S11 will be described with reference to FIGS. 3 and 4. FIG. 3 is a table showing data before the result of the coupled simulation is shaped into the learning data, and FIG. 4 is a table showing data after the result of the coupled simulation is shaped into the learning data.

FIG. 3 shows results of the coupled simulation to simulate a change in units of 100 msec using the micro-model set 10, and the results of the coupled simulation for inputs A, B, . . . are outputs a, b, . . . .

As the input A, A0 is input at time 0, and then A1, A2, . . . are input every 100 msec. Similarly, as the input B, B0 is input at the time 0, and then B1, B2, . . . are input every 100 msec.

As the output a, a0 is output at the time 0, and then a1, a2, . . . are output every 100 msec. Similarly, as the output b, b0 is output at the time 0, and then b1, b2, . . . are output every 100 msec.

When a calculation model to simulate a change in units of 1 sec using such results of the coupled simulation as inputs is derived, the macro-model learning unit 23 performs shaping into a data pair as shown in FIG. 4 of the input and output data at each time shown in FIG. 3 and output data after one second has elapsed and outputs the data pair.

That is to say, FIG. 4 shows inputs and outputs before simulation is performed and outputs after 1 sec has elapsed after simulation is performed, and the inputs and the outputs before simulation is performed are the same as those in FIG. 3. As the outputs after simulation is performed, a10, a11, a12, . . . output as the output a and b10, b11, b12, . . . output as the output b are shown.

Returning now to the description of the flowchart of FIG. 2, the macro-model learning unit 23 performs macro-model learning to derive a calculation model to estimate, from the learning data shaped in step S11, similar output data to that in the coupled simulation for any input data (step S12).

The results of the coupled simulation acquired from the simulation result DB 22 in the process of learning can be different pieces of data having similar features. For example, it is contemplated that, since the micro-model set 10 is a set of existing micro-models, results of simulation under various conditions are accumulated for the respective micro-models. In such a case, input and output data in time sequence when the coupled simulation is performed can be derived from known results of simulation of the micro-models, and the derived sequential data can be shaped to be output as the learning data without performing the coupled simulation using the micro-model set 10.

The macro-model learning unit 23 can perform a method of deriving the calculation model using any algorithm if the calculation model is a model that can estimate output data after a period of time has elapsed from particular input and output data, and, as for a configuration of the learning data, different data configurations according to the method of deriving the calculation model can be used. For example, as the method of deriving the calculation model, a known algorithm, such as supervised learning, unsupervised learning, and reinforcement learning, can be used.

A case where supervised learning using a neural network is applied as a method of generating a macro-model to infer an output obtained after a period of time has elapsed for any input in the overall simulation will be described as one example. Supervised learning herein refers to a scheme of providing a pair of input data and result data to a learning apparatus, learning features of the learning data, and inferring a result for any input.

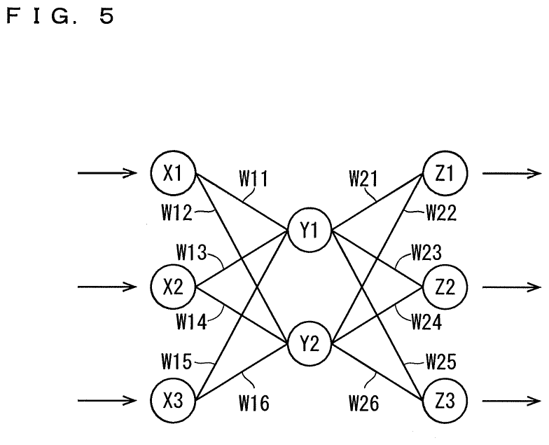

First, the neural network is a network that has an input layer and an output layer including a plurality of neurons and includes one or more middle layers. FIG. 5 is a diagram schematically showing one example of the neural network. The neural network shown in FIG. 5 is a three-layer neural network including an X layer as the input layer, a Z layer as the output layer, and a Y layer as a middle layer.

In a case of the three-layer neural network shown in FIG. 5, coefficients w11, w12, . . . of a weight W1 and coefficients w21, w22, . . . of a weight W2 between neurons are first randomly set and initialized at a learning stage. Next, pieces of input data are input from the learning data into respective neurons X1, X2, . . . of the input layer, and values obtained by multiplying the values input into the input layer by the coefficients of the weight W1 are input into respective neurons Y1 and Y2 of the middle layer. Results of learning at the neurons Y1 and Y2 are further multiplied by the coefficients of the weight W2 and input into respective neurons Z1, Z2, . . . of the output layer to finally determine output values. The output values for the input values vary depending on the coefficients of the weights W1 and W2.

A procedure to learn the neural network by supervised learning will be described next. In supervised learning, the learning data is divided into model generation data and test data for evaluating the validity of the learned neural network.

This processing is processing of dividing a set of pairs of the input data and the result data into a subset used for learning of the model as the model generation data and a subset used for verification of the learned model as the test data.

Description will be made on a case where there are Set1, Set2, Set3, . . . , and Set1000 as the pairs of the input data and the result data, for example. When the input data and the result data of Set1, Set2, Set3, . . . , and Set700 are provided to the learning apparatus for learning of the model, the input data of remaining Set701, . . . , and Set1000 are provided to the learned model, and obtained inferred values and the result data are verified, Set1, . . . , and Set700 are the model generation data, and Set701, . . . , and Set1000 are the test data.

Parameters of the weights of the neural network are adjusted using the model generation data in processing of procedures (A1) to (A5) described below, and whether sufficiently valid results of the simulation can be obtained using the adjusted parameters is verified by procedures (B1) to (B3) described below. A process of learning the neural network by the procedures (A1) to (A5) will be described below.

Procedure (A1): inputting the input data of the model generation data into each neuron of the input layer of the neural network and acquiring a value of each neuron of the output layer of the neural network thus obtained as the output data of the neural network.

As described previously, the model generation data is a set of pairs of the input data and the result data. Thus, when FIG. 4 is taken as an example, the input data of the model generation data corresponds to (A0, B0, . . . , a0, b0, . . . ), (A1, B1, . . . , a1, b1, . . . ), and the like, and the result data of the model generation data corresponds to (a10, b10, . . . ), (a11, b11, . . . ), and the like.

The output data of the neural network corresponds to a data pair obtained from each neuron of the output layer as a result of inputting the input data of the model generation data into each neuron of the input layer and propagating the input data from the middle layer to the output layer. A value of each neuron of the output layer corresponds to each item of the result data.

Procedure (A2): comparing the output data of the neural network as obtained and the result data of the model generation data, that is, the output data to be a correct answer and calculating an error.

Procedure (A3): correcting a weight coefficient between the output layer and the middle layer using back propagation to reduce the error calculated by the procedure (A2).

Back propagation is herein one of weight coefficient correction algorithms and is a known scheme of adjusting the weight coefficients so that a gradient of an error function is reduced to minimize the error. Use of this scheme allows for calculation of the weight coefficients between the output layer and the middle layer directly from the result data and the output data.

Procedure (A4): sequentially calculating errors in the middle layers from a middle layer close to the output layer from the error in the output layer and the weight coefficients between layers to the output layer using back propagation to also correct the weight coefficients between the middle layers.

Procedure (A5): correcting the weight coefficients between the middle layers to reduce the errors calculated by the procedure (A4).

A process of verifying the neural network by the procedures (B1) to (B3) will be described next.

Procedure (B1): inputting the input data of the test data into the neural network and acquiring the output data of the neural network thus obtained.

As described previously, the output data of the neural network is a value of each neuron of the output layer of the neural network and corresponds to each item of the result data of the model generation data and the result data of the test data.

Procedure (B2): comparing the acquired output data and the result data of the test data, that is, the output data to be a correct answer and calculating an error.

Procedure (B3): confirming that the error calculated by the procedure (B2) is sufficiently small.

The sufficiently small error herein indicates that an error of an output inferred by the learned model is small enough to be negligible in simulation using the model. A specific numerical value is determined depending on a value inferred by the model and a configuration of simulation. When the error is not sufficiently small, accuracy is improved by adjustment of various parameters used for learning, a change in learning algorithm, and the like.

In the present disclosure, when supervised learning using the neural network is applied, from the learning data obtained by input data shaping processing in step S11 in the flowchart of FIG. 2, input and output values in simulation at certain time is the input data for learning, and an output value after a period of time has elapsed since the time for the input data is the output data to be a correct answer for learning.

By performing processing of the learning process described above, the macro-model learning unit 23 (FIG. 1) generates and outputs the macro-model.

Use of supervised learning using the neural network for generation of the macro-model allows for a response to the overall simulation in which there are many pieces of input data.

We now return to the description of the block diagram of FIG. 1. The micro-model addition processing unit 30 includes an expanded coupled simulation unit 31 and an expanded model learning unit 32 and has a function to receive a new micro-model 12 developed separately from the micro-model set 10 as an input and update the macro-model 11 generated by the model generation processing unit 20 with a model into which the new micro-model 12 has been incorporated.

While it is contemplated that micro-models that are easily implemented are developed in advance, and the macro-model is generated from these micro-models to enable early application of the overall simulation, the micro-model addition processing unit 30 incorporates micro models that are gradually additionally developed into the macro-model 11 to enable expansion and update of a range of application of the overall simulation.

The expanded coupled simulation unit 31 is a simulation apparatus that performs the overall simulation using the existing micro-model set 10 and the added new micro-model 12 and couples inputs and outputs of the micro-model set 10 and the new micro-model 12 to implement the overall simulation while considering interactions between models due to inputs and outputs per simulation cycle between the models.

While processing of coupling the inputs and the outputs of the micro-model set and the new micro-model 12 is herein the same processing as processing of “coupling inputs and outputs of micro-models” performed by the coupled simulation unit 21 of the model generation processing unit 20 described previously, not only each micro-model of the micro-model set 10 but also the new micro-model 12 can be a target of coupling.

While processing of considering the interactions between the models due to the inputs and the outputs per simulation cycle between the models is the same processing as processing of “applying an input and an output per simulation cycle of each model to another model” performed by the coupled simulation unit 21 of the model generation processing unit 20 described previously, not only each micro-model of the micro-model set 10 but also the new micro-model 12 can be a target of application.

The micro-model addition processing unit 30 stores a result of the simulation in the simulation result DB 22 as with the model generation processing unit 20.

While the micro-model addition processing unit 30 receives the existing micro-model set 10 and the new micro-model 12 as inputs in the block diagram of FIG. 1, the macro-model 11 generated from the micro-model set 10 can be used in place of the micro-model set 10 as long as behavior of the coupled simulation using the micro-model set 10 can be simulated.

The macro-model can thereby be learned using a past result of the simulation using the existing micro-models without performing expanded coupled simulation by the expanded coupled simulation unit 31.

The expanded model learning unit 32 is a model generation apparatus that acquires a result of the coupled simulation performed by the expanded coupled simulation unit 31 from the simulation result DB 22, generates, from the acquired result of the simulation, an expanded macro-model to infer an output in the overall simulation into which the new micro-model 12 has been incorporated, and replaces the existing macro-model 11 with the expanded macro-model. The result of the simulation is shaped into the learning data, and the model is generated from the shaped learning data by the same method as the method used by the macro-model learning unit 23 of the model generation processing unit 20. This model is also generated by the procedures (A1) to (A5) and the procedures (B1) to (B3) described previously.

The expanded macro-model to infer the output in the overall simulation is herein a model to simulate the overall simulation using the micro-model set 10 and the new micro-model 12 and is, when the micro-model set 10 includes the new micro-model 12, a model equivalent to the macro-model generated by the macro-model learning unit 23.

By performing micro-model addition processing described above, the micro-model addition processing unit 30 can expand a region in which the simulation can be performed due to the overall simulation using the expanded macro-model obtained by incorporating the new micro-model 12 into the macro-model 11 generated by the model generation processing unit 20.

We now return to the description of the block diagram of FIG. 1. The simulation performing processing unit 40 includes an overall simulation performing unit 41 and has a function to receive the macro-model 11 as an input from the model generation processing unit 20 and output, upon input of a simulation initial condition 13, a simulation result 14 as a result of the overall simulation performed based on them. The overall simulation performing unit 41 can also receive an additional correction model 42 to correct a change and an effect not considered by the existing micro-models as an input.

While the model generation processing unit 20 and the simulation performing processing unit 40 are shown as a portion of the simulation apparatus 100 in the block diagram of FIG. 1, they may be implemented as different apparatuses independent of each other if the macro-model 11 can be transferred.

The overall simulation performing unit 41 is a simulation apparatus that receives the macro-model 11 output from the model generation processing unit 20 and the simulation initial condition 13 as inputs and outputs the simulation result 14 as a result of the overall simulation. The simulation initial condition 13 is a value designated by a performer when the overall simulation is performed and is data corresponding to an initial value input into the macro-model 11.

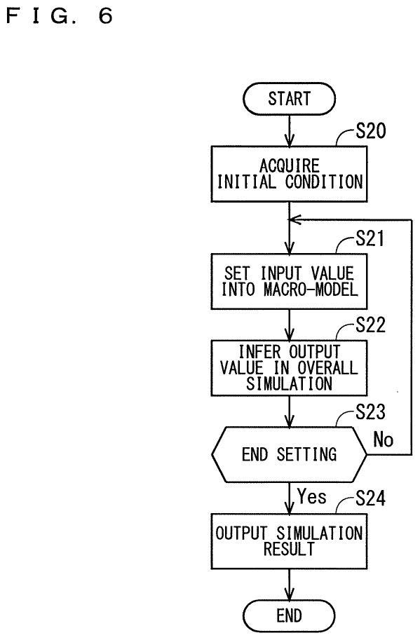

FIG. 6 is a flowchart for explaining a process of performing the overall simulation by the overall simulation performing unit 41. The process of performing the overall simulation will be described below with reference to FIG. 6.

Upon starting performing the overall simulation, the overall simulation performing unit 41 first acquires the simulation initial condition 13 and determines input data to be an initial input into the macro-model 11 (step S20). In this case, when a method of generating the macro-model 11 is supervised learning shown as one example, not only an input value in the coupled simulation but also an initial output value is required to be determined.

That is to say, when the macro-model 11 is learned using data of pairs of an input and an output before simulation is performed and an output after simulation is performed as shown in FIG. 4, data of an input and an output is required to be input into the macro-model 11, and the initial output value is basically an output value corresponding to an initial state assumed by the simulation. In a case of simulation of an air conditioner, for example, the air conditioner is stopped at the start of the simulation, so that an output of a fan, a compressor, and the like is a stopped state, and air and the like in a framework are to have the same value as a value of a room temperature as the initial output value.

Similarly, depending on a scheme of generating the macro-model 11, a parameter other than an input value that can be acquired by the coupled simulation is sometimes required as the input data to be the initial input. This is because not all the input values can be determined from an output estimated by the macro-model in some cases, and, in this case, a parameter is required to determine remaining one or more input values.

When airflow and a temperature in a room are simulated, for example, the airflow and the temperature in the room are output from the result of the simulation, but heat propagation and the like from a wall and a window of the room are required to be input in any way. When it is a fixed value, the value is required to be provided, and, when it is determined in time sequence, a parameter sequence is required to be provided. It is sometimes provided as the initial input because a coefficient and the like when an input value is calculated from an output value of the macro-model vary depending on a simulation condition.

Returning now to the description of the flowchart of FIG. 6, the input data determined in step S20 is input into the acquired macro-model 11 (step S21).

Next, a result of inference of the macro-model 11 for the input is acquired and recorded as the output value in the overall simulation (step S22).

That is to say, the macro-model 11 has learned a result of the overall simulation by coupling of the micro-models using the macro-model learning unit 23, so that an output of the macro-model 11 is the result of inference of the output value in the overall simulation as it is.

Next, whether a sufficient simulation result of the overall simulation has been obtained is determined in step S23, and, when a necessary simulation result has been obtained (if Yes), inputs and outputs of the overall simulation having been recorded so far are output as the simulation result 14 (step S24). On the other hand, when an insufficient simulation result has been obtained (if No), next input data into the macro-model 11 is determined from the output value obtained in step S22, and processing in and after step S21 is repeated.

Determination on the simulation result is herein made by determining whether an end condition of the simulation is satisfied. For example, when a change in airflow and temperature for one hour under a certain condition is checked in simulation of the airflow and the temperature, the end condition is an elapse of one hour on the simulation, and, when one hour has not been elapsed, it is determined that an insufficient simulation result has been obtained.

Via processing in steps S20 to S24 described above, the overall simulation performing unit 41 performs the overall simulation using the macro-model 11.

The additional correction model 42 is a correction model to simulate an element not considered by the existing micro-models included in the micro-model set 10 and an effect of a change in parameter in the process of performing the overall simulation by the overall simulation performing unit 41 and is a model to correct age deterioration, a change in external environment, and the like, for example. In a case of age deterioration, the additional correction model 42 is a model to correct a delay of a reaction of an actuator, reduction in output, and the like. In a case of the change in external environment, the additional correction model 42 is a model to correct a change in temperature, atmospheric pressure, humidity, and the like due to a season and weather.

By performing the overall simulation using the additional correction model 42 as described above, the element not considered by the existing micro-models and the effect of the change in parameter can be simulated.

When a model to make correction as the additional correction model 42 is extrapolated, step S22 (FIG. 6) in the process of performing the overall simulation is corrected. After the output value is inferred from the macro-model 11 in step S22, the inferred output value is corrected using the additional correction model 42.

One example of correction is correction due to age deterioration, and, when operation of a product having a part movable by a motor is simulated, for example, a rotational speed and a torque output of the motor inferred by the macro-model are corrected using a correction model for age deterioration to reduce a torque and the rotational speed.

When simulation does not end in the end determination in step S23, that is, when the end condition of the simulation is not satisfied, an output value after correction is determined as next input data, and processing in and after step S21 is repeated.

We now return to the description of the block diagram of FIG. 1. The model relearning processing unit 50 includes a re-simulation unit 52 and a model relearning unit 53 and has a function to reperform, when a condition out of a learning range of the macro-model appears in the process of performing the overall simulation by the simulation performing processing unit 40, the coupled simulation on the condition and update the macro-model 11 with a relearned macro-model having been relearned using a result of the simulation.

The condition out of the learning range of the macro-model herein indicates a case where data input in the simulation of the macro-model is not in a range of the simulation condition when learn data is generated.

For example, when a macro-model having learned a result of simulation in which an input value of a room temperature is within 10° C. to 30° C. is used, the condition out of the learning range of the macro-model has appeared if the input value of the room temperature calculated from the output value inferred by the macro-model falls below 10° C. during the simulation using the macro-model. A condition providing a result of calculation in which the value falls below 10° C. is an out-of-learning range simulation condition 51.

The re-simulation unit 52 is a simulation apparatus that receives the out-of-learning range simulation condition 51 and the micro-model set 10 as inputs and reperforms the coupled simulation. The re-simulation unit 52 has a function to store a result of the reperformed simulation in the simulation result DB 22 and update the learning data of the macro-model.

The model relearning unit 53 has a function to acquire the result of the simulation for learning of the macro-model from the simulation result DB 22 updated by the re-simulation unit 52 and relearn the macro-model 11. Processing of shaping the result of the simulation into the learning data and a method of learning the macro-model are a processing and a method that are the same as those performed by the macro-model learning unit 23 of the model generation processing unit 20.

By including the model relearning processing unit 50, even if the condition out of the learning range of the macro-model appears, the simulation can be reperformed to include the condition, and the macro-model can be relearned using the result of the reperformed simulation.

### Hardware Configuration of Simulation Apparatus

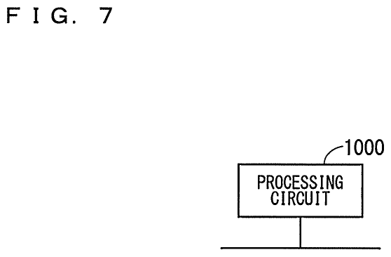

Each of the components of the simulation apparatus 100 can be configured using a computer and is implemented by the computer executing a program. That is to say, the simulation apparatus 100 is implemented by a processing circuit 1000 shown in FIG. 7, for example. A processor, such as a central processing unit (CPU) and a digital signal processor (DSP), is applied to the processing circuit 1000, and a program stored in a storage apparatus is executed to perform the function of each of the components.

Dedicated hardware may be applied to the processing circuit 1000. When the processing circuit 1000 is the dedicated hardware, the processing circuit 1000 corresponds to a single circuit, a composite circuit, a programmed processor, a parallel programmed processor, an application specific integrated circuit (ASIC), a field-programmable gate array (FPGA), and a combination thereof, for example.

The functions of the components of the simulation apparatus 100 may be implemented by individual processing circuits or may collectively be implemented by a single processing circuit.

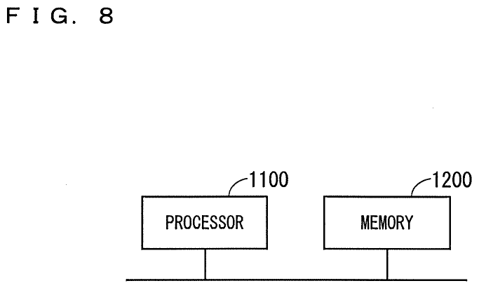

FIG. 8 shows a hardware configuration when the processing circuit 1000 is configured using a processor. In this case, the functions of the components of the simulation apparatus 100 are implemented by combination with software and the like (software, firmware, or software and firmware). The software and the like are described as a program and stored in memory 1200. A processor 1100 functioning as the processing circuit 1000 reads and executes the program stored in the memory 1200 (storage apparatus) to implement the functions of the components. That is to say, it can be said that the program causes a computer to perform procedures and methods of operation of the components of the simulation apparatus 100.

The memory 1200 herein may be, for example, nonvolatile or volatile semiconductor memory, such as RAM, ROM, flash memory, erasable programmable read only memory (EPROM), and electrically erasable programmable read only memory (EEPROM), a hard disk drive (HDD), a magnetic disk, a flexible disk, an optical disc, a compact disc, a mini disc, a digital versatile disc (DVD), a drive device thereof, and the like or any storage medium to be used in the future.

A configuration in which the functions of the components of the simulation apparatus 100 are implemented by any one of hardware and software and the like has been described above. The configuration, however, is not limited to this configuration, and one or more of the components of the simulation apparatus 100 may be implemented by the dedicated hardware, and the other one or more of the components may be implemented by the software and the like. For example, the functions of one or more of the components can be implemented by the processing circuit 1000 as the dedicated hardware, and the functions of the other one or more of the components can be implemented by the processing circuit 1000 as the processor 1100 reading and executing the program stored in the memory 1200.

While the present disclosure has been described in detail, the foregoing description is in all aspects illustrative and not restrictive. It is understood that numerous unillustrated modifications can be devised without departing from the scope of the present disclosure.

Embodiments can freely be combined with each other and can be modified or omitted as appropriate within the scope of the present disclosure.

1. A simulation apparatus comprising:
coupled simulation circuitry that performs coupled simulation to combine a plurality of micro-models each being a simulation model for a limited element;
macro-model learning circuitry that learns, from a result of the coupled simulation performed by the coupled simulation circuitry, a correspondence between an input and an output in overall simulation to simulate an entire simulation target and generates a macro-model to infer an output after a period of time has elapsed for an input; and
overall simulation performing circuitry that performs the overall simulation using the macro-model generated by the macro-model learning circuitry.

2. The simulation apparatus according to claim 1, wherein
the overall simulation performing circuitry performs the overall simulation while correcting the output inferred by the macro-model using a correction model to simulate an element not considered by the plurality of micro-models.

3. The simulation apparatus according to claim 1 further comprising
a model relearning circuitry that reperforms, when data input in the overall simulation using the macro-model is not in a range of a simulation condition for the macro-model learning circuitry, the coupled simulation on a condition including the data and updates the macro-model with a relearned macro-model having been relearned using a result of the reperformed coupled simulation, wherein
the overall simulation performing circuitry performs the overall simulation using the relearned macro-model.

4. The simulation apparatus according to claim 1 further comprising:
expanded coupled simulation circuitry that performs the coupled simulation using the plurality of micro-models and a plurality of added new micro-models; and
expanded model learning circuitry that generates, from a result of the coupled simulation performed by the expanded coupled simulation circuitry, an expanded macro-model to infer an output in the overall simulation into which the plurality of new micro-models have been incorporated and replaces the macro-model with the expanded macro-model.

5. The simulation apparatus according to claim 4, wherein
the expanded coupled simulation circuitry performs the couple simulation using, in place of the plurality of micro-models, the macro-model generated based on the plurality of micro-models and the plurality of new micro-models.

6. The simulation apparatus according to claim 1, wherein
the macro-model learning circuitry generates the macro-model by supervised learning using a neural network.
